(19) United States
(12) Patent Application Publication
(10) Pub. No.: US 2026/0180513 A1
(43) Pub. Date: Jun. 25, 2026

(54) AMPLIFIER DEVICE ABLE TO PROCESS MULTIPLE SETS OF INPUT SIGNALS

(71) Applicant: REALTEK SEMICONDUCTOR CORPORATION, Hsinchu (TW)

(72) Inventor: Shih-Hsiung Huang, Hsinchu (TW)

(21) Appl. No.: 19/423,295

(22) Filed: Dec. 17, 2025

(30) Foreign Application Priority Data
Dec. 23, 2024 (TW) 113150239

(51) Int. Cl. H03F 1/02; H03F 3/45; H03K 3/037

(52) U.S. Cl. CPC H03F 1/0216; H03F 3/45179; H03K 3/037

(57) ABSTRACT

An amplifier device includes a first input pair circuit, a second input pair circuit, and a latch circuit. The first input pair circuit amplifies a first set of input signals. The second input pair circuit amplifies a second set of input signals, in which a conductivity type of the first input pair circuit is different from that of the second input pair circuit. The first input pair circuit and the second input pair circuit are further coupled in series through output nodes and generate amplified signals through the output nodes, the first input pair circuit and the second input pair circuit are coupled between a first power supply node and a second power supply node, and the first power supply node and the second power supply node receive different power supply voltages. The latch circuit generates output signals according to the amplified signals.

### BACKGROUND OF THE INVENTION

### 1. Field of the Invention

The present disclosure relates to an amplifier device, and more particularly, to an amplifier device that may amplify multiple sets of input signals simultaneously through the same bias current.

### 2. Description of Related Art

In some application scenarios, an amplifier that may amplify multiple sets of signals simultaneously is used. For example, an input to a quantizer in a delta-sigma modulator is typically a combination of multiple sets of input signals. In the existing approach a double differential amplifier may be employed to process the multiple sets of input signals. However, the double differential amplifier is generally implemented by combining two independent amplifiers, which results in a larger circuit area and higher power consumption. If the number of sets of input signals to be processed is more, the area and power consumption will be significantly increased.

### SUMMARY OF THE INVENTION

In some aspects, an object of the present disclosure is to, but not limited to, provide an amplifier device that may amplify multiple sets of input signals simultaneously through the same bias current, so as to make an improvement to the prior art.

In some aspects, an amplifier device includes a first input pair circuit, a second input pair circuit, and a latch circuit. The first input pair circuit is configured to amplify a first set of input signals. The second input pair circuit is configured to amplify a second set of input signals, in which a conductivity type of the first input pair circuit is different from a conductivity type of the second input pair circuit. The first input pair circuit and the second input pair circuit are further coupled in series through a plurality of output nodes and generate a plurality of amplified signals through the plurality of output nodes, the first input pair circuit and the second input pair circuit are coupled between a first power supply node and a second power supply node, and the first power supply node and the second power supply node receive different power supply voltages. The latch circuit is configured to generate a plurality of output signals according to the plurality of amplified signals.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of an amplifier device 100 according to some embodiments of the present disclosure.

FIG. 2 illustrates a schematic diagram of an amplifier device according to some embodiments of the present disclosure.

FIG. 3 illustrates a schematic diagram of an amplifier device according to some embodiments of the present disclosure.

FIG. 4 illustrates a schematic diagram of an amplifier device according to some embodiments of the present disclosure.

FIG. 5 illustrates a schematic diagram of an amplifier device according to some embodiments of the present disclosure.

FIG. 6 illustrates a schematic diagram of an amplifier device according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

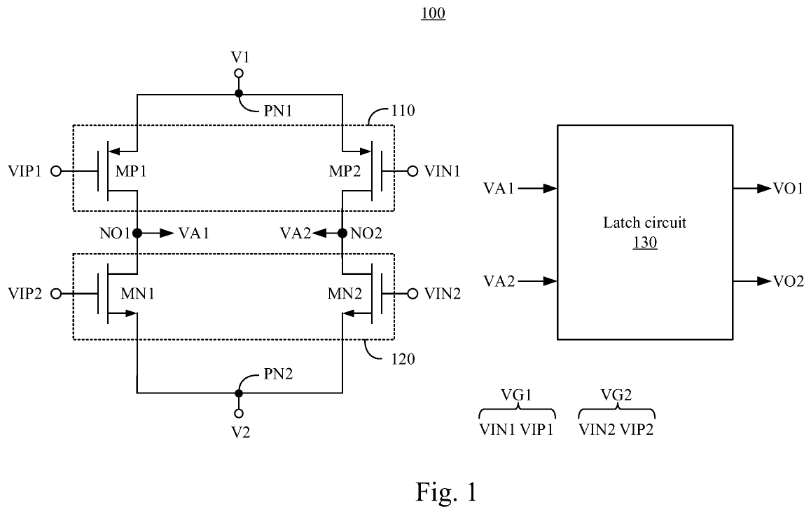

FIG. 1 illustrates a schematic diagram of an amplifier device 100 according to some embodiments of the present disclosure. The amplifier device 100 may simultaneously amplify a first set of input signals VG1 and a second set of input signals VG2 to generate an output signal VO1 and an output signal VO2. In some embodiments, the first set of input signals VG1 includes an input signal VIP1 and an input signal VIN1, which may be differential signals. Similarly, in some embodiments, the second set of input signals VG2 includes an input signal VIP2 and an input signal VIN2, which may be differential signals.

The amplifier device 100 includes an input pair circuit 110, an input pair circuit 120, and a latch circuit 130. The input pair circuit 110 and the input pair circuit 120 are coupled in series through an output node NO1 and an output node NO2 and are coupled between a power supply node PN1 and a power supply node PN2. The power supply node PN1 and the power supply node PN2 receive different power supply voltages. For example, the power supply node PN1 receives a power supply voltage V1, and the power supply node PN2 receives a power supply voltage V2 (which may be lower than the power supply voltage V1). The input pair circuit 110 amplifies the first set of input signals VG1, and the input pair circuit 120 amplifies the second set of input signals VG2, so as to generate an amplified signal VA1 and an amplified signal VA2 through the output node NO1 and the output node NO2, respectively. With the above configuration, the input pair circuit 110 and the input pair circuit 120 may be biased by the same current flowing through the power supply node PN1 and the power supply node PN2, and may simultaneously amplify multiple sets of input signals.

The latch circuit 130 is coupled to the output node NO1 and the output node NO2 to receive the amplified signal VA1 and the amplified signal VA2 and is configured to generate the output signal VO1 and the output signal VO2 according to the amplified signal VA1 and the amplified signal VA2. In some embodiments, the latch circuit 130 may be a positive feedback circuit that may be employed to further amplify the amplified signal VA1 and the amplified signal VA2 to a higher voltage swing. In some embodiments, the latch circuit 130 may also be biased by the current flowing through the power supply node PN1 and the power supply node PN2 (that is, the latch circuit 130 may be coupled between the power supply node PN1 and the power supply node PN2), but the present disclosure is not limited thereto. In some embodiments, the latch circuit 130 is powered by other power supply voltages.

In some embodiments, the latch circuit 130 may be implemented with two cross-coupled inverter circuits. In some embodiments, the latch circuit 130 may be implemented with a positive feedback circuit with a reset mechanism. In some embodiments, the latch circuit 130 may be implemented with a positive feedback circuit with a dynamic latched mechanism. The various implementations of the latch circuit 130 described above are given for illustrative purposes, and the present disclosure is not limited thereto. Various latch circuits 130 that may be employed to increase signal swing is within the contemplated scope of the present disclosure.

In some embodiments, a conductivity type of the input pair circuit 110 is different from a conductivity type of the input pair circuit 120. In some embodiments, the conductivity type corresponds to a conductivity type of transistors employed in the input pair circuit. For example, the transistors employed in the input pair circuit 110 are all P-type transistors, and the transistors employed in the input pair circuit 120 are all N-type transistors, so that the input pair circuit 110 and the input pair circuit 120 have opposite conductivity types (that is, P-type and N-type). In other words, the conductivity type of the input pair circuit 110 is determined by doping material characteristics of internal transistors, and similarly, the conductivity type of the input pair circuit 120 is determined by doping material characteristics of internal transistors.

In greater detail, the input pair circuit 110 includes a P-type transistor MP1 and a P-type transistor MP2, and the input pair circuit 120 includes an N-type transistor MN1 and an N-type transistor MN2. A first terminal of the P-type transistor MP1 (e.g., a source) is coupled to the power supply node PN1 to receive the power supply voltage V1, a second terminal of the P-type transistor MP1 (e.g., a drain) is coupled to the output node NO1 to generate the amplified signal VA1, and a control terminal of the P-type transistor MP1 (e.g., a gate) receives an input signal VIP1 in the first set of input signals VG1, so as to amplify the input signal VIP1. Similarly, a first terminal of the P-type transistor MP2 is coupled to the power supply node PN1 to receive the power supply voltage V1, a second terminal of the P-type transistor MP2 is coupled to the output node NO2 to generate the amplified signal VA2, and a control terminal of the P-type transistor MP2 receives an input signal VIN1 in the first set of input signals VG1, so as to amplify the input signal VIN1. A first terminal of the N-type transistor MN1 (e.g., a drain) is coupled to the output node NO1 to generate the amplified signal VA1, a second terminal of the N-type transistor MN1 (e.g., a source) is coupled to the power supply node PN2 to receive the power supply voltage V2, and a control terminal of the N-type transistor MN1 (e.g., a gate) receives an input signal VIP2 in the second set of input signals VG2, so as to amplify the input signal VIP2. Similarly, a first terminal of the N-type transistor MN2 is coupled to the output node NO2 to generate the amplified signal VA2, a second terminal of the N-type transistor MN2 is coupled to the power supply node PN2 to receive the power supply voltage V2, and a control terminal of the N-type transistor MN2 receives an input signal VIN2 in the second set of input signals VG2, so as to amplify the input signal VIN2.

Through circuit analysis, it can be derived that, in the above configuration, the amplified signal VA1 and the amplified signal VA2 satisfy the following equation:

$$- ( VA 1 - VA 2 ) = ( VIP 2 - VIN 2 ) \times {ℊ}_{m n} \times {r}_{o p} + ( VIP 1 - VIN 1 ) \times {ℊ}_{m p} \times {r}_{o n}$$

where gₘₙ is a transconductance value of each of the N-type transistor MN1 and the N-type transistor MN2, rₒₚ is an output impedance of each of the P-type transistor MP1 and the P-type transistor MP2, gₘₚ is a transconductance value of each of the P-type transistor MP1 and the P-type transistor MP2, and rₒₙ is an output impedance of each of the N-type transistor MN1 and the N-type transistor MN2. From the above equation, it may be understood that, in some embodiments, a weight ratio of the first set of input signals VG1 (i.e., the input signal VIP1 and the input signal VIN1) and the second set of input signals VG2 (i.e., the input signal VIP2 and the input signal VIN2) in the amplified signal VA1 and amplified signal VA2 may be adjusted by setting the sizes of the P-type transistor MP1, the P-type transistor MP2, the N-type transistor MN1, and the N-type transistor MN2.

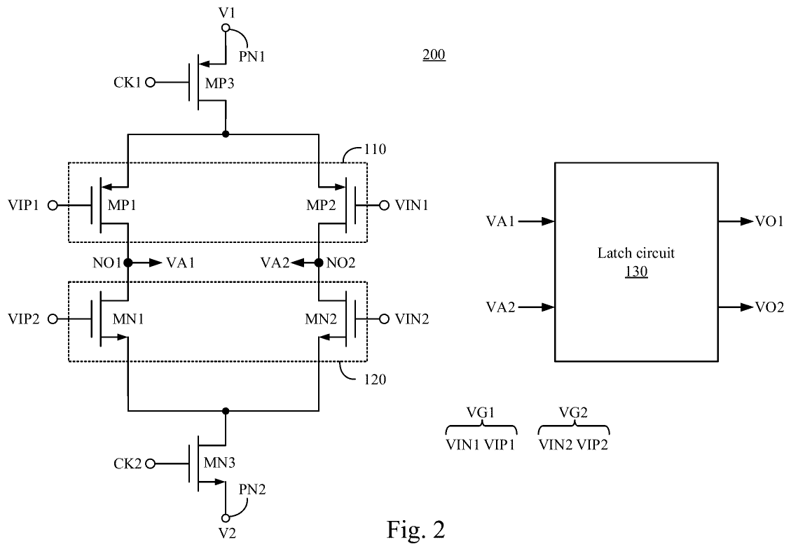

FIG. 2 illustrates a schematic diagram of an amplifier device 200 according to some embodiments of the present disclosure. Different from FIG. 1, the amplifier device 200 further includes a P-type transistor MP3 and an N-type transistor MN3. The P-type transistor MP3 is coupled between the power supply node PN1 and the input pair circuit 110 and is configured to be turned on according to a clock signal CK1. Similarly, the N-type transistor MN3 is coupled between the power supply node PN2 and the input pair circuit 120 and is configured to be turned on according to a clock signal CK2. In greater detail, a first terminal of the P-type transistor MP3 is coupled to the power supply node PN1, a second terminal of the P-type transistor MP3 is coupled to a first terminal of the P-type transistor MP1 and a first terminal of the P-type transistor MP2, and a control terminal of the P-type transistor MP3 receives the clock signal CK1. A first terminal of the N-type transistor MN3 is coupled to a second terminal of the N-type transistor MN1 and a second terminal of the N-type transistor MN2, a second terminal of the N-type transistor MN3 is coupled to the power supply node PN2, and a control terminal of the N-type transistor MN3 receives the clock signal CK2.

In this example, the clock signal CK1 and the clock signal CK2 may be two clock signals with opposite phases. Thus, the P-type transistor MP3 and the N-type transistor MN3 may operate as switches and may be turned on simultaneously according to the clock signal CK1 and the clock signal CK2 to provide the power supply voltage V1 and the power supply voltage V2 to the input pair circuit 110 and the input pair circuit 120 for signal amplification. In other words, when the amplifier device 200 does not need to be used, the P-type transistor MP3 and the N-type transistor MN3 may not be turned on to further save overall power consumption. According to the above, the amplifier device 200 may be regarded as a dynamic amplifier.

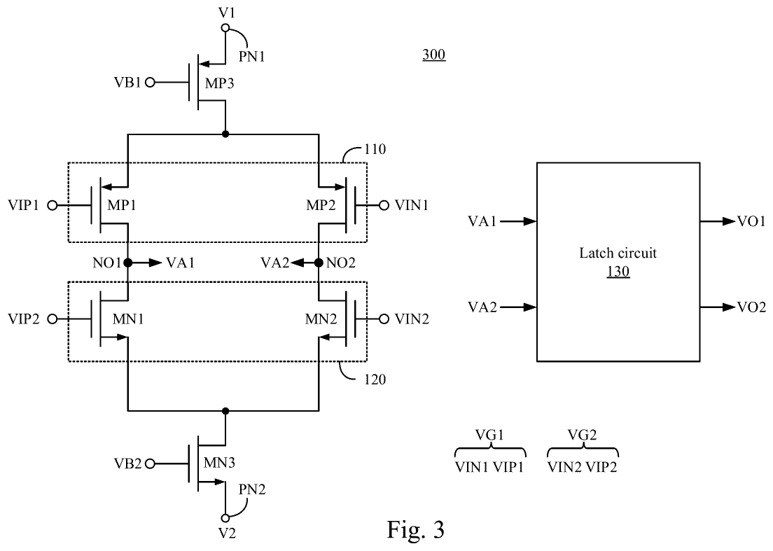

FIG. 3 illustrates a schematic diagram of an amplifier device 300 according to some embodiments of the present disclosure. Different from FIG. 2, in the amplifier device 300, the P-type transistor MP3 is configured to be biased by a voltage VB1 (instead of receiving the clock signal CK1), and the N-type transistor MN3 is configured to be biased by a voltage VB2 (instead of receiving the clock signal CK2). In this example, the P-type transistor MP3 and the N-type transistor MN3 may operate as current sources and may fixedly bias the input pair circuit 110 and the input pair circuit 120. In other words, the amplifier device 300 may be regarded as a static amplifier.

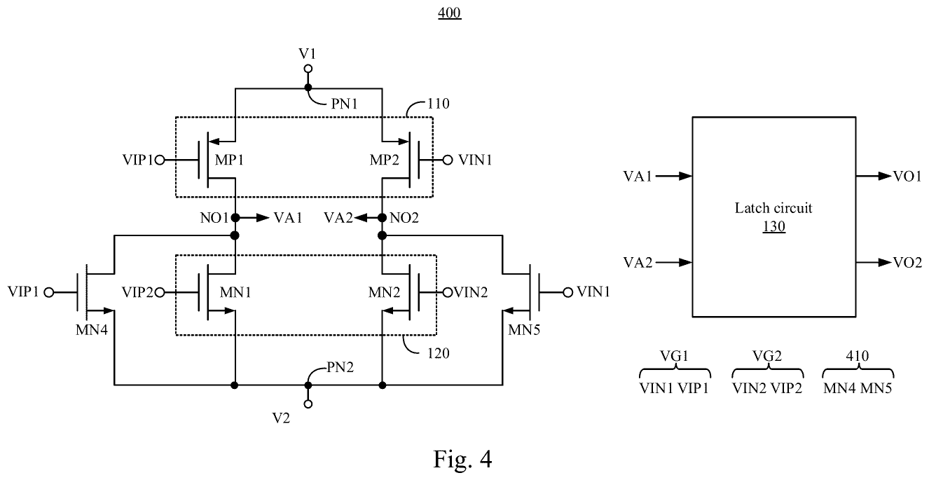

FIG. 4 illustrates a schematic diagram of an amplifier device 400 according to some embodiments of the present disclosure. Different from FIG. 1, in this example, the amplifier device 400 further includes an input pair circuit 410 that is configured to amplify the first set of input signals VG1 to generate the amplified signal VA1 and the amplified signal VA2. The input pair circuit 410 and the input pair circuit 120 are coupled in parallel and between the output nodes NO1 and NO2 and the power supply node PN2. A conductivity type of the input pair circuit 410 is opposite to a conductivity type of the input pair circuit 110, and a conductivity type of the input pair circuit 410 is the same as a conductivity type of the input pair circuit 120. For example, transistors employed in each of the input pair circuit 410 and the input pair circuit 120 are N-type transistors, and transistors employed in the input pair circuit 110 are P-type transistors.

In greater detail, the input pair circuit 410 includes an N-type transistor MN4 and an N-type transistor MN5. A first terminal of the N-type transistor MN4 is coupled to the output node NO1 to generate the amplified signal VA1, a second terminal of the N-type transistor MN4 is coupled to the power supply node PN2, and a control terminal of the N-type transistor MN4 receives an input signal VIP1 of the first set of input signals VG1. A first terminal of the N-type transistor MN5 is coupled to the output node NO2 to generate the amplified signal VA2, a second terminal of the N-type transistor MN5 is coupled to the power supply node PN2, and a control terminal of the N-type transistor MN5 receives an input signal VIN1 of the first set of input signals VG1. With the above configuration, the first set of input signals VG1 may be amplified through the input pair circuit 110 and the input pair circuit 410.

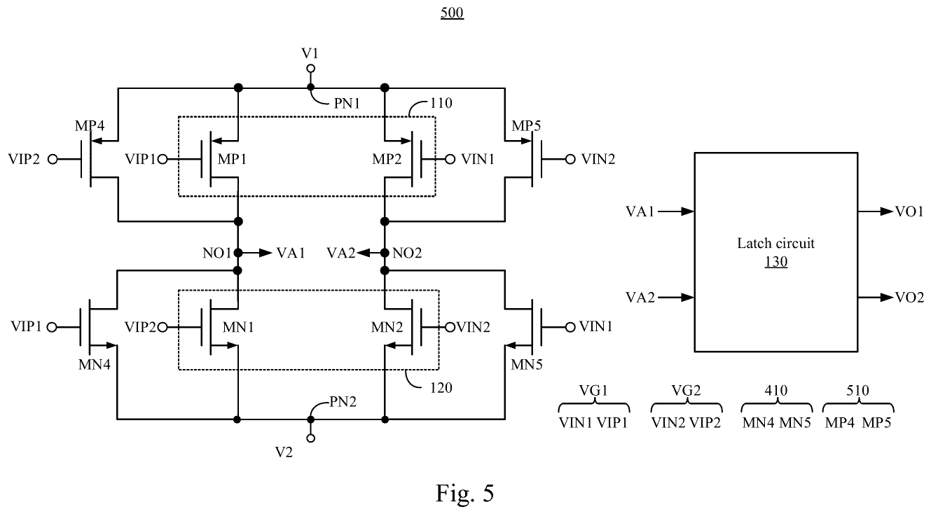

FIG. 5 illustrates a schematic diagram of an amplifier device 500 according to some embodiments of the present disclosure. Different from FIG. 4, in this example, the amplifier device 500 further includes an input pair circuit 510 that is configured to amplify the second set of input signals VG2 to generate the amplified signal VA1 and the amplified signal VA2. The input pair circuit 510 and the input pair circuit 110 are coupled in parallel and between the power supply node PN1 and the output nodes NO1 and NO2. A conductivity type of the input pair circuit 510 is opposite to a conductivity type of the input pair circuit 120, and a conductivity type of the input pair circuit 510 is the same as a conductivity type of the input pair circuit 110. For example, transistors employed in each of the input pair circuit 510 and the input pair circuit 110 are P-type transistors, and transistors employed in the input pair circuit 120 are N-type transistors.

In greater detail, the input pair circuit 510 includes a P-type transistor MP4 and a P-type transistor MP5. A first terminal of the P-type transistor MP4 is coupled to the power supply node PN1, a second terminal of the P-type transistor MP4 is coupled to the output node NO1 to generate the amplified signal VA1, and a control terminal of the P-type transistor MP4 receives an input signal VIP2 of the second set of input signals VG2. A first terminal of the P-type transistor MP5 is coupled to the power supply node PN1, a second terminal of the P-type transistor MP5 is coupled to the output node NO2 to generate the amplified signal VA2, and a control terminal of the P-type transistor MP5 receives an input signal VIN2 of the second set of input signals VG2. With the above configuration, the first set of input signals VG1 may be amplified through the input pair circuit 110 and the input pair circuit 410, and the second set of input signals VG2 may be amplified through the input pair circuit 120 and the input pair circuit 510.

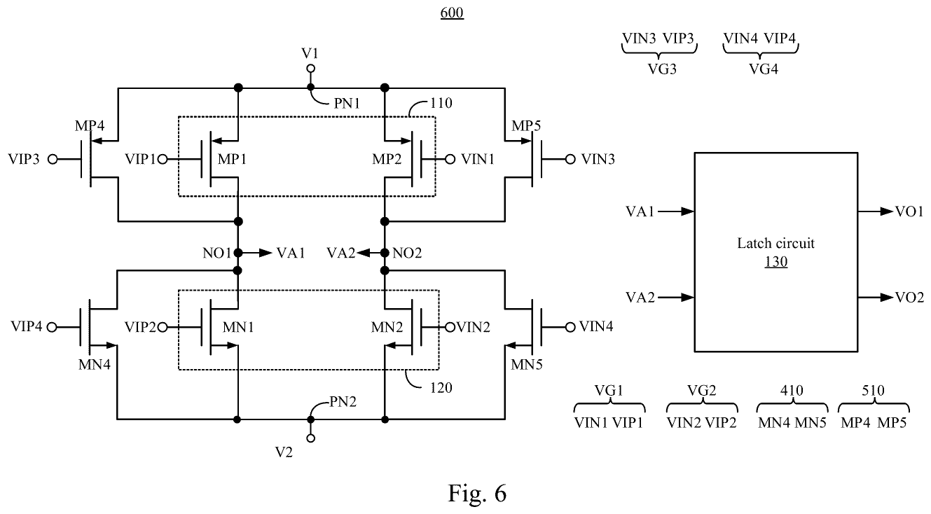

FIG. 6 illustrates a schematic diagram of an amplifier device 600 according to some embodiments of the present disclosure. Different from FIG. 5, in this example, the input pair circuit 510 is configured to amplify a third set of input signals VG3 (which may include an input signal VIP3 and an input signal VIN3), and the input pair circuit 410 is configured to amplify a fourth set of input signals VG4 (which may include an input signal VIP4 and an input signal VIN4) to generate the amplified signal VA1 and the amplified signal VA2. In greater detail, a control terminal of the P-type transistor MP4 receives the input signal VIP3 of the third set of input signals VG3, a control terminal of the P-type transistor MP5 receives the input signal VIN3 of the third set of input signals VG3, a control terminal of the N-type transistor MN4 receives the input signal VIP4 of the fourth set of input signals VG4, and a control terminal of the N-type transistor MN5 receives the input signal VIN4 of the fourth set of input signals VG4. A conductivity type of the input pair circuit 510 is the same as a conductivity type of the input pair circuit 110. A conductivity type of the input pair circuit 410 is the same as a conductivity type of the input pair circuit 120. Other circuit configurations are the same as those in the above embodiments, and thus are not repeated herein. With the above configuration, the amplifier device 600 may simultaneously amplify more sets of input signals.

It should be understood that the above circuit configurations in the above embodiments are given for illustrative purposes, and the present disclosure is not limited thereto. In different embodiments, the input pair circuit 110 may be coupled to the input pair circuit 120 through one or more additional circuits, in which the one or more additional circuits may include, but are not limited to, a resistor, a capacitor, and/or a diode, a resistor, a switch implemented with transistors, and the like, which may be configured to adjust internal circuit levels.

As described above, the amplifier device provided by some embodiments of the present disclosure may employ multiple sets of input pair circuits under the same bias current to simultaneously amplify multiple sets of input signals, thereby achieving amplifier applications with smaller area and lower power consumption.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. An amplifier device, comprising:
a first input pair circuit configured to amplify a first set of input signals;
a second input pair circuit configured to amplify a second set of input signals, wherein a conductivity type of the first input pair circuit is different from a conductivity type of the second input pair circuit,
wherein the first input pair circuit and the second input pair circuit are further coupled in series through a plurality of output nodes and generate a plurality of amplified signals through the plurality of output nodes, the first input pair circuit and the second input pair circuit are coupled between a first power supply node and a second power supply node, and the first power supply node and the second power supply node receive different power supply voltages; and
a latch circuit configured to generate a plurality of output signals according to the plurality of amplified signals.

2. The amplifier device of claim 1, wherein the first input pair circuit comprises a plurality of P-type transistors, and the second input pair circuit comprises a plurality of N-type transistors.

3. The amplifier device of claim 1, wherein the first input pair circuit comprises:
a first P-type transistor configured to amplify a first input signal in the first set of input signals and coupled between the first power supply node and a first output node of the plurality of output nodes; and
a second P-type transistor configured to amplify a second input signal in the first set of input signals and coupled between the first power supply node and a second output node of the plurality of output nodes.

4. The amplifier device of claim 1, wherein the second input pair circuit comprises:
a first N-type transistor configured to amplify a first input signal in the second set of input signals and coupled between the second power supply node and a first output node of the plurality of output nodes; and
a second N-type transistor configured to amplify a second input signal in the second set of input signals and coupled between the second power supply node and a second output node of the plurality of output nodes.

5. The amplifier device of claim 1, further comprising:
a first transistor coupled between the first power supply node and the first input pair circuit and configured to be turned on according to a first clock signal; and
a second transistor coupled between the second power supply node and the second input pair circuit and configured to be turned on according to a second clock signal.

6. The amplifier device of claim 1, further comprising:
a first transistor coupled between the first power supply node and the first input pair circuit and biased by a first voltage; and
a second transistor coupled between the second power supply node and the second input pair circuit and biased by a second voltage.

7. The amplifier device of claim 1, further comprising:
a third input pair circuit configured to amplify the first set of input signals to generate the plurality of amplified signals, wherein the third input pair circuit and the second input pair circuit are coupled in parallel and between the plurality of output nodes and the second power supply node, and a conductivity type of the third input pair circuit is opposite to the conductivity type of the first input pair circuit.

8. The amplifier device of claim 7, further comprising:
a fourth input pair circuit configured to amplify the second set of input signals to generate the plurality of amplified signals, wherein the fourth input pair circuit and the first input pair circuit are coupled in parallel and between the plurality of output nodes and the first power supply node, and a conductivity type of the fourth input pair circuit is opposite to the conductivity type of the second input pair circuit.

9. The amplifier device of claim 1, further comprising:
a third input pair circuit configured to amplify a third set of input signals to generate the plurality of amplified signals, wherein the third input pair circuit and the first input pair circuit are coupled in parallel and between the plurality of output nodes and the first power supply node; and
a fourth input pair circuit configured to amplify a fourth set of input signals to generate the plurality of amplified signals, wherein the fourth input pair circuit and the second input pair circuit are coupled in parallel and between the plurality of output nodes and the second power supply node.

10. The amplifier device of claim 9, wherein a conductivity type of the third input pair circuit is the same as the conductivity type of the first input pair circuit.

11. The amplifier device of claim 9, wherein a conductivity type of the fourth input pair circuit is the same as the conductivity type of the second input pair circuit.
